(19) United States
(12) Patent Application Publication
(10) Pub. No.: US 2014/0050646 A1
(43) Pub. Date: Feb. 20, 2014

(54) SUPERHARD BORON OXYNITRIDE AND METHOD FOR PRODUCING THE SAME

(71) Applicant: Akitaka SAWAMURA, Osaka-shi (JP)

(72) Inventor: Akitaka SAWAMURA, Osaka-shi (JP)

(73) Assignee: Sumitomo Electric Industries, Ltd., Osaka (JP)

(21) Appl. No.: 13/586,496

(22) Filed: Aug. 15, 2012

(51) Int. Cl. C01B 35/18; C30B 7/10

(52) U.S. Cl. 423/277; 117/71

(57) ABSTRACT

B₃NO₃ of the present invention has a rock salt type crystal structure to thereby have a bulk modulus higher than that of c-BN.

### BACKGROUND OF THE INVENTION

1. Field of the Invention

The present invention relates to superhard boron oxynitride and a method for producing the same.

2. Description of the Background Art

Hard materials such as diamond and ceramics have been industrially widely used in a broad range of areas such as wear-resistant components and cutting tools. However, due to recent advancement of technology, a material having a higher hardness is demanded.

In such a situation, in recent years, hard materials having a higher hardness have been frequently examined by predictively evaluating the hardness of or the possibility of synthesis of the hard materials by means of first-principles calculations.

For example, an article has been published in which β type C₃N₄ modeled from β type Si₃N₄, which is used as a principal component of practical ceramics, is predicted to have a hardness comparable to that of diamond (A. Y. Liu and M. L. Cohen, Phys. Rev. B41 (1990), 10727: Document 1).

Then, zinc blende type having vacancy (A. Y. Liu and R. M. Wentzcovitch, Phys. Rev. B50 (1994), 10362: Document 2), α type (D. M. Teter and R. J. Hemley, U.S. Pat. No. 5,981,094, 1999: Document 3 and D. M. Teter and R. J. Hemley, Science 271 (1996), 53: Document 4), willemite II type (Document 3), and spinel type (S. D. Mo, L. Ouyang, W. Y. Ching, I. Tanaka, Y. Koyama, and R. Riedel, Phys. Rev. Lett. 83 (1999), 5046: Document 5) have been proposed. Among them, willemite II type C₃N₄ has been predicted to exceed diamond in hardness.

In addition, in O. U. Okeke and J. E. Lowther, Phys. Rev. B77(2008), 094129: Document 6 and O. U. Okeke and J. E. Lowther, WO2009/112934: Document 7, predictions about a spinel type M₃NO₃ hard material have been made. In the “M₃NO₃, ” “M” is III group elements including B to In. A spinel type M₃NO₃ hard material is a material derived from the idea that in spinel type C₃N₄, C, which is a IV group element, is replaced with a III group element and three Ns of four Ns are replaced with O in view of charge balance.

### SUMMARY OF THE INVENTION

Hard materials that do not contain C are thought to be suitable as materials for tools for processing steel materials. Thus, also with regard to materials that do not contain C, a hard material that is harder than cubic boron nitride (c-BN) and has a high hardness comparable to that of diamond is demanded.

Therefore, an object of the present invention is to provide a novel hard material having a hardness higher than that of c-BN and a method for producing the same.

(1) The present invention is a superhard boron oxynitride comprising: B₃NO₃ having a rock salt type crystal structure to thereby have a bulk modulus higher than that of c-BN.

(2) The present invention is also a single crystal of B₃NO₃ of the above (1).

(3) The present invention is also a polycrystal of B₃NO₃ of the above (1).

(4) The present invention is also a sintered body containing B₃NO₃ of the above (1).

(5) The present invention is also a wear-resistant material containing B₃NO₃ of the above (1).

(6) The present invention is also a cutting tool containing B₃NO₃ of the above (1).

(7) The present invention is also a grinding tool containing B₃NO₃ of the above (1).

(8) The present invention is also a method for producing B₃NO₃ having a rock salt type crystal structure to thereby have a bulk modulus higher than that of c-BN, the method comprising the step of combining boron, nitrogen, and oxygen under a pressure of at least 750 GPa.

### BRIEF DESCRIPTION OF THE DRAWINGS

FIG. 1 is a schematic diagram illustrating the crystal structure of B₃NO₃ of an embodiment of the present invention;

FIG. 2 is a table showing crystal structure data of α type B₃NO₃ and β type B₃NO₃ after optimization;

FIG. 3 is a table showing crystal structure data of willemite II type B₃NO₃ and zinc blende type B₃NO₃ after optimization;

FIG. 4 is a table showing crystal structure data of spinel type B₃NO₃ and rock salt type B₃NO₃ after optimization;

FIG. 5 is a table showing the value of each parameter of each material which is obtained by fitting a Murnaghan equation of state;

FIG. 6 is a graph showing a result obtained by recalculating a relationship between volume and energy from each parameter obtained by fitting the Murnaghan equation of state;

FIG. 7 is a graph showing a result obtained by converting the relationship between volume and energy in each material shown in FIG. 6 into a relationship between pressure and enthalpy; and

FIG. 8 is a table showing bulk moduli of the six materials, including the rock salt type B₃NO₃ of the present embodiment, as well as c-BN and diamond.

### DESCRIPTION OF THE PREFERRED EMBODIMENTS

Hereinafter, a preferred embodiment of the present invention will be described with reference to the drawings.

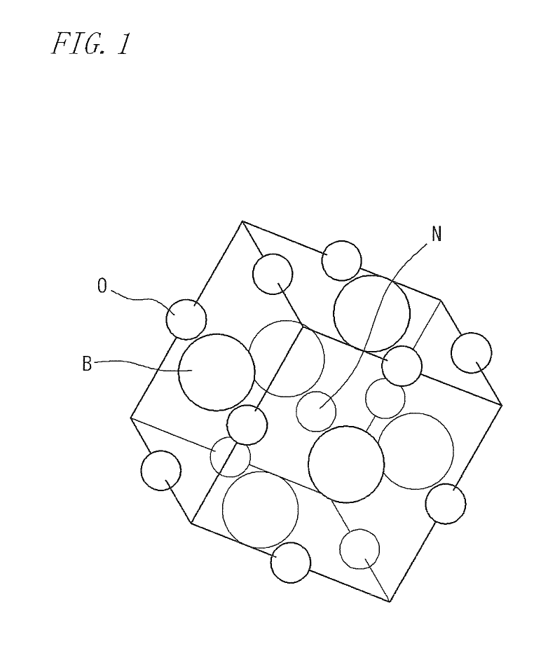

FIG. 1 is a schematic diagram illustrating the crystal structure of B₃NO₃ of the present embodiment. In FIG. 1, the crystal structure of the B₃NO₃ of the present embodiment is a rock salt type.

The rock salt type B₃NO₃ of the present embodiment has a bulk modulus higher than that of c-BN, since its crystal structure is a rock salt type. When a rock salt type crystal structure is applied to B₃NO₃, B is located at the position of Na, and N and O are located at the position of Cl. Thus, the B₃NO₃ having the rock salt type crystal structure has vacancy in some of the positions of Na.

The rock salt type B₃NO₃ of the present embodiment has a higher value of bulk modulus, which is an index of hardness, than that of c-BN, and thus is a very hard material.

Therefore, it is possible to industrially widely use the rock salt type B₃NO₃ of the present embodiment. For example, a single crystal or polycrystal of the rock salt type B₃NO₃ of the present embodiment is synthesized, and sintered bodies are formed by using these materials and can be used for machining tools for processing metal, ceramics, and the like, such as cutting tools and grinding tools. A machining tool that employs the rock salt type B₃NO₃ of the present embodiment can have enhanced cutting performance or grinding ability, since the rock salt type B₃NO₃ is very hard.

In addition, the rock salt type B₃NO₃ of the present embodiment is very hard and hence has excellent wear resistance. Thus, when the rock salt type B₃NO₃ of the present embodiment is applied to a portion requiring wear resistance such as a sliding portion of a machine component, the hardness of the rock salt type B₃NO₃ allows for improving wear resistance such as preventing the sliding portion from being worn out.

With regard to the rock salt type B₃NO₃ of the present embodiment, the inventor of the present invention initially obtained a detailed crystal structure, calculated a relationship between volume and energy from the obtained crystal structure, obtained a bulk modulus on the basis of the relationship, and evaluated the hardness of the material. In addition, the inventor also evaluated the possibility of synthesis on the basis of the relationship between volume and energy. In the present embodiment, the hardness of the material was evaluated based on bulk modulus.

Further, in addition to the crystal structure of the rock salt type B₃NO₃ of the present embodiment, the inventor also conducted the same evaluation on α type B₃NO₃, β type B₃NO₃, willemite II type B₃NO₃, zinc blende type B₃NO₃, and spinel type B₃NO₃ as comparative examples.

First, methods for obtaining crystal structure data and a bulk modulus will be described.

A detailed crystal structure of each material was calculated as numerical data on the basis of first-principles calculations.

The crystal structure was calculated based on the density functional theory and by a pseudopotential method which avoids handling core electrons which hardly contribute to properties. As approximation regarding interaction between electrons, local density approximation was used. As the pseudopotential method, a norm-conserving type was used.

In addition, as software for the above calculations, ABINIT (X. Gonze et. Al., Z. Kristallogr. 220 (2005), 558: Document 8 and X. Gonze et. Al., Computer Phys. Comm. 180 (2009), 2582: Document 9) was used.

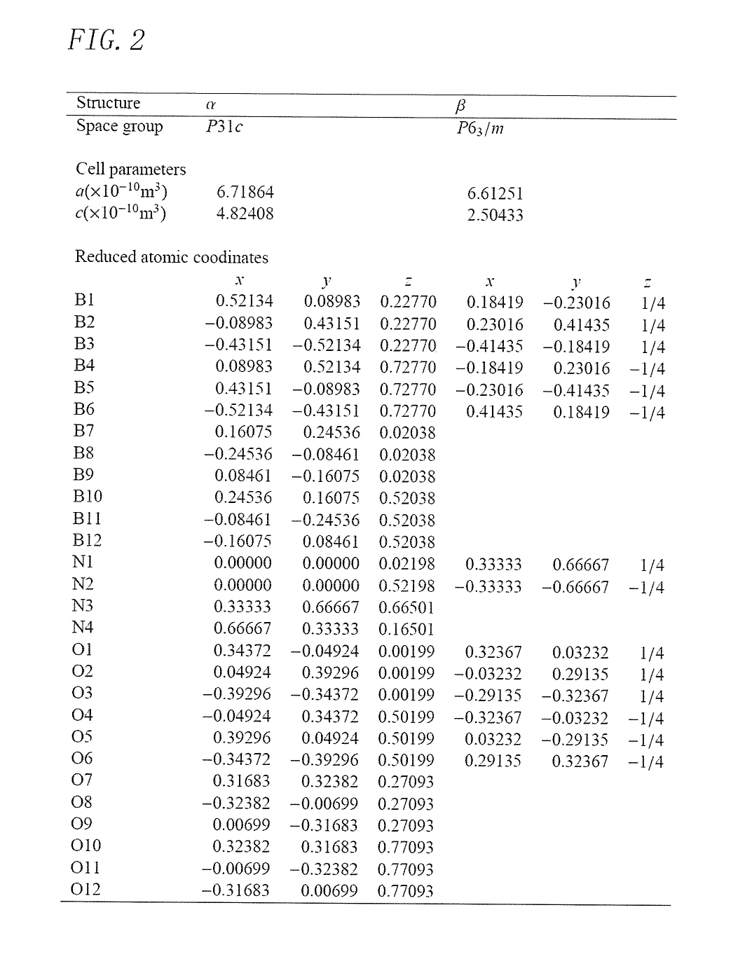

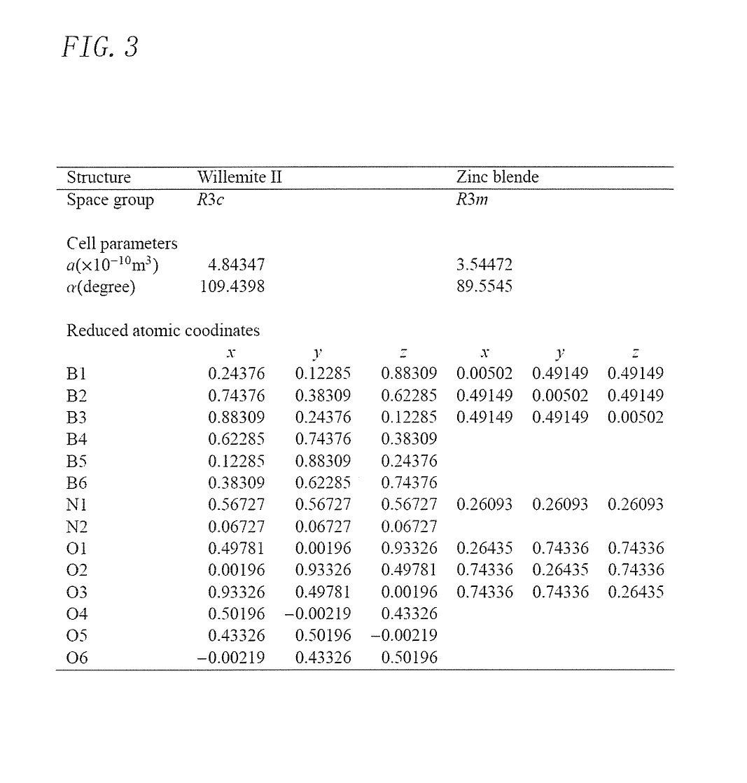

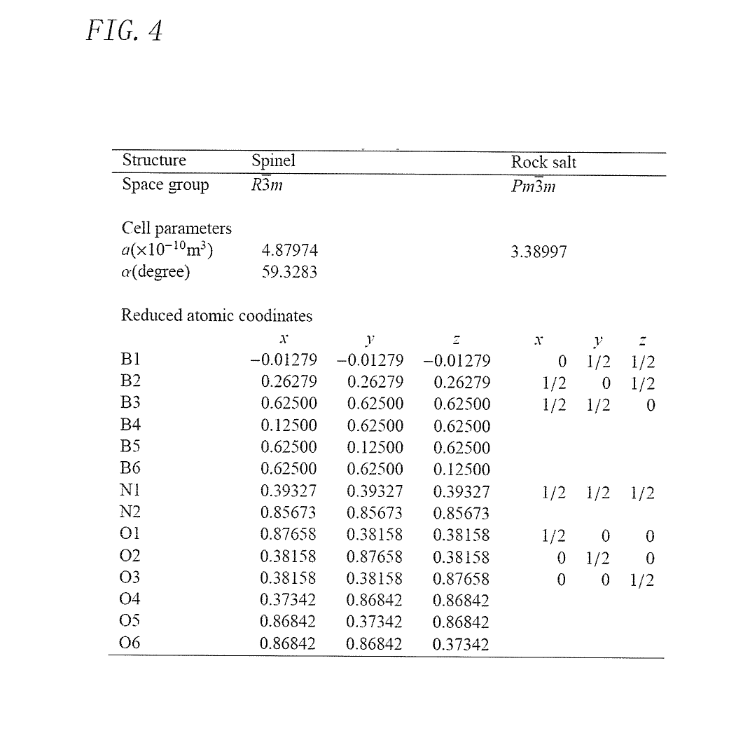

FIG. 2 shows examples of crystal structure data of the α type B₃NO₃ and the β type B₃NO₃ after optimization, FIG. 3 shows examples of crystal structure data of the willemite II type B₃NO₃ and the zinc blende type B₃NO₃ after optimization, and FIG. 4 shows examples of crystal structure data of the spinel type B₃NO₃ and the rock salt type B₃NO₃ after optimization.

A bulk modulus is obtained from the crystal structure data. The crystal structure data that were calculated on the basis of the above first-principles calculations and optimized were used for obtaining a relationship between volume and energy in each material.

Specifically, an energy was calculated by designating a volume and optimizing the other degrees of freedom, whereby variation of energy with respect to volume variation in each material was obtained.

Next, a relationship between volume and energy in each material was fitted with a Murnaghan equation of state represented by the following Equation (1).

$$E = \frac{{B}_{0} V}{{B}^{′} ( {B}^{′} - 1 )} [ {B}^{′} ( 1 - \frac{{V}_{0}}{V} ) + {( \frac{{V}_{0}}{V} )}^{{B}^{′}} - 1 ] + {E}_{0} \qquad ( 1 )$$

The Murnaghan equation of state represented by the above Equation (1) is an equation representing the relationship between volume V and energy E and includes, as adjustable parameters, a volume V₀ under zero pressure, an energy E₀ under zero pressure, a bulk modulus B₀ under zero pressure, and pressure dependence B′ of the bulk modulus under zero pressure. The pressure dependence B′ is represented by the following Equation (2).

$${B}^{′} = \frac{\partial {B}_{0}}{\partial P} \qquad ( 2 )$$

Each parameter in the above Equation (1) is adjusted to fit the Equation (1) to the relationship between volume and energy in each material, and the value of each parameter when fitting is obtained.

By so doing, the bulk modulus B₀ under zero pressure, which is a value for evaluating the hardness of the material, can be obtained.

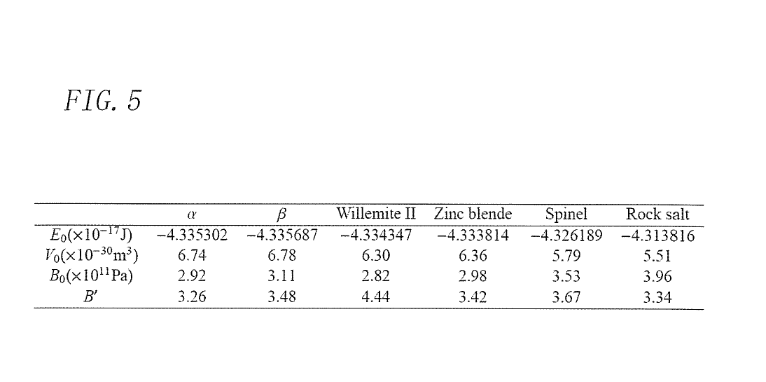

FIG. 5 shows the value of each parameter of each material which is obtained by fitting the Murnaghan equation of state. It is recognized that the bulk modulus B₀ of the rock salt type B₃NO₃ of the present embodiment is higher than those of the other materials.

Next, the possibility of synthesis of the rock salt type B₃NO₃ of the present embodiment will be described.

The possibility of synthesis was evaluated by obtaining a relationship between pressure and enthalpy by using each parameter described above.

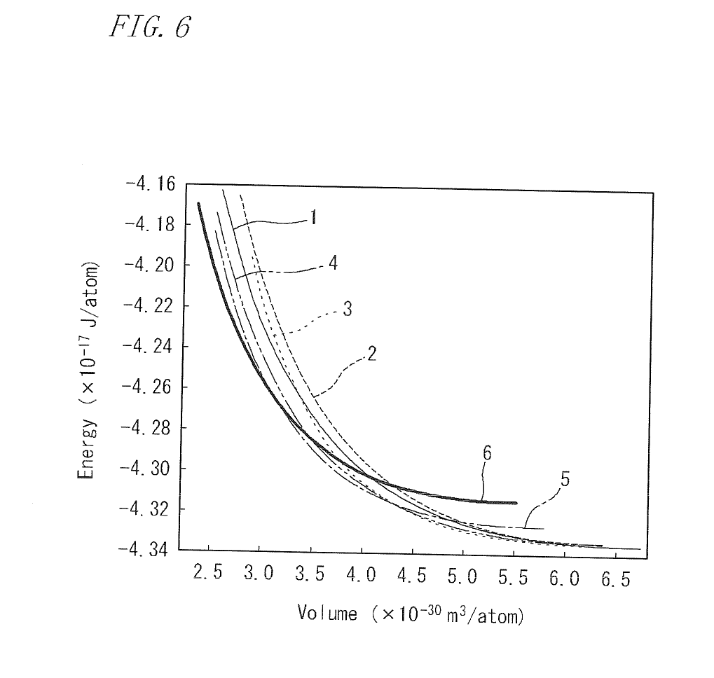

The relationship between volume and energy was recalculated by using each parameter described above. The result is shown in FIG. 6. In FIG. 6, the horizontal axis indicates volume, and the vertical axis indicates energy. A solid line 1 indicates a relationship between volume and energy in the α type B₃NO₃; a dashed line 2 indicates a relationship between volume and energy in the β type B₃NO₃; a dashed line 3 indicates a relationship between volume and energy in the willemite II type B₃NO₃; an alternate long and two short dashes line 4 indicates a relationship between volume and energy in the zinc blende type B₃NO₃; an alternate long and short dash line 5 indicates a relationship between volume and energy in the spinel type B₃NO₃; and a solid line 6 indicates a relationship between volume and energy in the rock salt type B₃NO₃.

Here, a pressure P which is an easily-controllable variable in producing each material is represented by the following Equation (3).

$$P = - \frac{\partial E}{\partial V} \qquad ( 3 )$$

In addition, an enthalpy H which is a relative index of whether it is in a phase that is easily generated under a finite pressure is represented by the following Equation (4).

H=E+PV (4)

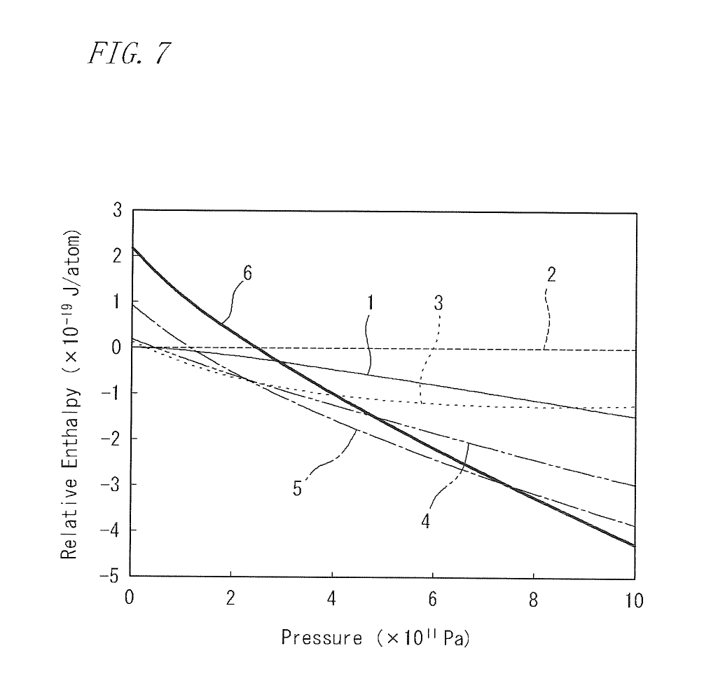

On the basis of the above Equations (3) and (4), the relationship between volume and energy in each material shown in FIG. 6 was converted into a relationship between pressure and enthalpy. The result is shown in FIG. 7. In FIG. 7, the horizontal axis indicates pressure, and the vertical axis indicates enthalpy. A solid line 1 indicates a relationship between pressure and enthalpy in the α type B₃NO₃; a dashed line 2 indicates a relationship between pressure and enthalpy in the β type B₃NO₃; a dashed line 3 indicates a relationship between pressure and enthalpy in the willemite II type B₃NO₃; an alternate long and two short dashes line 4 indicates a relationship between pressure and enthalpy in the zinc blende type B₃NO₃; an alternate long and short dash line 5 indicates a relationship between pressure and enthalpy in the spinel type B₃NO₃; and a solid line 6 indicates a relationship between pressure and enthalpy in the rock salt type B₃NO₃.

The enthalpy of each material in FIG. 7 is represented as a relative value based on the enthalpy of the β type B₃NO₃.

The enthalpy H indicates that the material having the smallest value of the enthalpy H is stable under equal pressure. In FIG. 7, the β type B₃NO₃ is the most stable under zero pressure, and the willemite II type B₃NO₃ becomes stable with pressurization. With further pressurization, the spinel type B₃NO₃ becomes stable around 200 GPa, and the rock salt type B₃NO₃ becomes stable when the pressure reaches around 750 GPa.

In other words, in FIG. 7, the enthalpy H of the rock salt type B₃NO₃ is the smallest under a pressure equal to or higher than about 750 GPa. Thus, it is recognized that if the β type B₃NO₃ can be synthesized as a precursor, it is possible to synthesize the rock salt type B₃NO₃ by pressurizing the β type B₃NO₃ at least to 750 GPa or more.

As a specific method for producing the rock salt type B₃NO₃ of the present embodiment, the following method is considered. Specifically, boron, nitrogen, and oxygen, which are raw materials, are put into a vessel together, and pressurized to 750 GPa or more while being kept at 1000 to several thousands ° C. By so doing, boron, nitrogen, and oxygen within the vessel are combined to obtain rock salt type B₃NO₃. The pressure during the pressurization is based on the above-described evaluation with the enthalpy H.

Next, evaluation of the bulk modulus will be described. In the present embodiment, with regard to c-BN and diamond as well, a bulk modulus, which is an index of hardness, was obtained by the same method as that for the six materials described above.

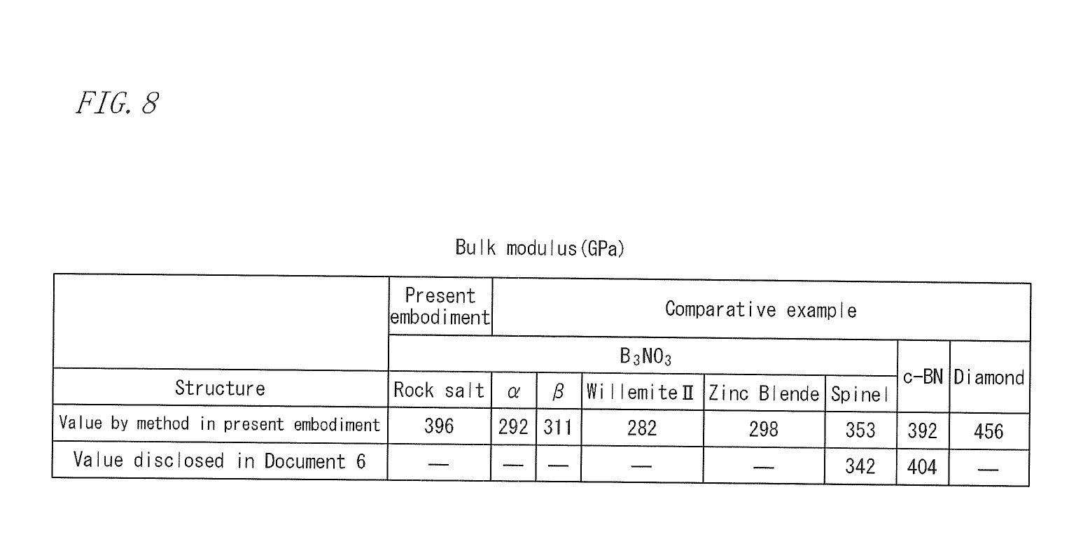

FIG. 8 shows the bulk moduli of the above-described six materials, including the rock salt type B₃NO₃ of the present embodiment, as well as c-BN and diamond.

In FIG. 8, when the bulk moduli obtained by the method in the present embodiment are compared to each other, the bulk modulus of the rock salt type B₃NO₃ of the present embodiment is 396 GPa which is lower than the bulk modulus of diamond but is higher than those of any of the materials including c-BN and the spinel type B₃NO₃ proposed in Document 6.

It should be noted that Document 6 discloses that the bulk modulus of c-BN is 404 GPa and the bulk modulus of the spinel type B₃NO₃ is 342 GPa. When these values are compared to the bulk modulus of the rock salt type B₃NO₃ of the present embodiment obtained by the method in the present embodiment, the value of the rock salt type B₃NO₃ of the present embodiment is higher than that of the spinel type B₃NO₃ in Document 6 but lower than the bulk modulus of c-BN in Document 6.

The reason is thought to be that a result of calculation of a bulk modulus by first-principles calculations slightly varies depending on the calculation method and setting of parameters. Thus, it is inappropriate to simply compare values obtained by different methods.

In principle, the bulk modulus of each material should be compared by relative comparison of values obtained by the same method, and it can be detei iiined that the bulk modulus of the rock salt type B₃NO₃ of the present embodiment obtained by the method in the present embodiment is relatively higher than the bulk modulus of c-BN.

From the above, it is clearly understood that the rock salt type B₃NO₃ of the present embodiment has a bulk modulus higher than that of c-BN.

Note that the embodiment disclosed herein is merely illustrative in all aspects and should not be recognized as being restrictive. The scope of the present invention is defined by the scope of the claims rather than by the meaning described above, and is intended to include meaning equivalent to the scope of the claims and all modifications within the scope.

What is claimed is:

1. A superhard boron oxynitride comprising:
B₃NO₃ having a rock salt type crystal structure to thereby have a bulk modulus higher than that of c-BN.

2. A single crystal of B₃NO₃ according to claim 1.

3. A polycrystal of B₃NO₃ according to claim 1.

4. A sintered body containing B₃NO₃ according to claim 1.

5. A wear-resistant material containing B₃NO₃ according to claim 1.

6. A cutting tool containing B₃NO₃ according to claim 1.

7. A grinding tool containing B₃NO₃ according to claim 1.

8. A method for producing B₃NO₃ having a rock salt type crystal structure to thereby have a bulk modulus higher than that of c-BN, the method comprising the step of:
combining boron, nitrogen, and oxygen under a pressure of at least 750 GPa.
